(19) United States
(12) Patent Application Publication
(10) Pub. No.: US 2004/0212086 A1
(43) Pub. Date: Oct. 28, 2004

(54) Semiconductor apparatus and production method thereof

(75) Inventors: Yoshihisa Dotta, Nara-shi (JP); Toshio Kimura, Kitakatsuragi-gun (JP); Hideyuki Kurimoto, Tenri-shi (JP)

Correspondence Address: NIXON & VANDERHYE, PC, 1100 N GLEBE ROAD, 8TH FLOOR, ARLINGTON, VA, 22201-4714, US

(73) Assignee: SHARP KABUSHIKI KAISHA, Osaka (JP)

(21) Appl. No.: 10/828,475

(22) Filed: Apr. 21, 2004

(30) Foreign Application Priority Data
Apr. 28, 2003 (JP) 2003-123773

(51) Int. Cl. H01L 23/48

(52) U.S. Cl. 257/737

(57) ABSTRACT

A semiconductor apparatus includes (i) a semiconductor substrate, (ii) a field oxide film, formed in a surface of the semiconductor substrate, having an aperture section, (iii) a electrode pad formed on the field oxide film, and (iv) a penetration electrode electrically connected to the electrode pad via the aperture section of the field oxide film and a hole formed in the semiconductor substrate. The hole is formed in the aperture section of the field oxide film, when perpendicularly viewing the semiconductor substrate.

This Nonprovisional application claims priority under 35 U.S.C. § 1119(a) on Patent Application No. 2003/123773 filed in Japan on Apr. 28, 2003, the entire contents of which are hereby incorporated by reference.

### FIELD OF THE INVENTION

The present invention relates to a semiconductor apparatus having a penetration electrode, and to a method for manufacturing the semiconductor apparatus.

### BACKGROUND OF THE INVENTION

An electrode of a conventional semiconductor apparatus is typically arranged such that (i) a field oxide film is formed on a surface of a semiconductor substrate, (ii) a metal pattern, in which a metal film of various types and an interlayer insulating film are layered, is formed on the field oxide film, and (iii) a protective film made of an oxide film or a nitride film is further formed on the metal pattern. If necessary, a second protective film made of polyimide may be further formed. In the protective film, an aperture is formed, and a metal electrode pad is formed so as to be exposed in the aperture. Wire-bonding or the like is carried out to the metal electrode pad so that the semiconductor apparatus can send/receive a signal to/from outside.

In recent years, there has been a demand for a compact mobile apparatus having thinner and smaller size and higher performance. Accordingly, there has been a demand for making a semiconductor apparatus smaller, thinner, and lighter, and for having higher density.

To meet the demands, proposed are (i) a multi-chip package, in which a plurality of semiconductor apparatuses are layered in a single package, and (ii) a three-dimensionally layered semiconductor apparatus.

Of these conventional semiconductor apparatuses, a semiconductor apparatus, having a penetration electrode and having no electrically conductive lead or wire, is hopeful especially because of excellence in smallness, thinness, lightness, and high-density. Such a penetration electrode is formed by forming a through-hole in a semiconductor substrate of the semiconductor apparatus, forming a conductor layer in the through-hole, and electrically connecting upper and bottom surfaces of the semiconductor substrate.

This type of semiconductor apparatus having a penetration electrode is disclosed, for example, in Japanese Laid-Open Patent Application Tokukaihei 10-223833/1998 (published on Aug. 21, 1998), or in Japanese Laid-Open Patent Application Tokukaihei 11-345933/1999 (published on Feb. 14, 1999), or the like.

Described in the Japanese Laid-Open Patent Application Tokukaihei 10-223833/1998 is a structure and a method for manufacturing a multi-chip semiconductor apparatus. In each semiconductor chip of the multi-chip semiconductor apparatus, a penetration electrode is formed in an upper surface of the semiconductor substrate which includes a semiconductor element, and a thinning treatment is carried out with respect to the semiconductor substrate from a bottom surface of the semiconductor substrate so that the penetration electrode is exposed. A plurality of the semiconductor chips thus obtained are layered, thereby realizing the multi-chip semiconductor apparatus.

Described in the Japanese Laid-Open Patent Application Tokukaihei 11-345933/1999 is a multi-chip semiconductor apparatus and a method for manufacturing the same. In the multi-chip semiconductor apparatus, a plurality of semiconductor chips, each having a penetration electrode with the use of electrically conductive pastes, are layered via gold bump electrodes, respectively.

In each patent document, a plurality of semiconductor apparatuses are layered successfully in high density, by using the respective penetration electrodes, without causing packaging area to enlarge.

As described above, in cases where a penetration electrode is formed in a semiconductor substrate in which a semiconductor element has already provided, the penetration electrode is formed in a field area of the substrate. The field area indicates an area where no semiconductor element is provided.

Here, the following description deals with an example of a semiconductor apparatus having a penetration electrode in a metal electrode pad, which is formed in the semiconductor substrate and which serves as an input/output terminal, with reference to FIG. 16 through FIG. 19.

As shown in FIG. 16, in a semiconductor apparatus, a field oxide film 102, an insulating protective film 103, and a metal electrode pad 104 are formed on an upper surface of a semiconductor substrate 101. On a bottom surface of the semiconductor substrate 101, an insulating film 112 is formed. Further, formed is a penetration electrode 115 penetrating the metal electrode pad 104, the field oxide film 102, the semiconductor substrate 101 made of silicon, and the insulating film 112, respectively. Note that an insulating film 109 is formed between the penetration electrode 115 and the semiconductor substrate 101.

Alternatively, as shown in FIG. 17, in order to form the penetration electrode, a semiconductor apparatus may be so arranged that a penetration electrode 115 is formed in a field area of the semiconductor substrate 101 and is connected to the metal electrode pad 104, which serves as an input/output terminal of the semiconductor apparatus, via a connecting wire 121.

Although a variety of methods for manufacturing the penetration electrode have been proposed, such methods include the following steps which are described below with reference to FIG. 18 and FIG. 19.

As shown in FIG. 18, a mask 107, used for forming the penetration electrode, is formed above the semiconductor substrate 101, and then a part of the metal electrode pad 104 (the metal film 110) and a part of the field oxide film 102 are removed in this order by carrying out the dry etching. Thereafter, a hole 106 is formed in the semiconductor substrate 101.

Then, as shown in FIG. 19, an insulating film 109, made of an oxide film, a nitride film, an organic insulating material, or the like, is formed in the hole 106 so as to insulate the internal surface of the hole 106 formed in the semiconductor substrate 101.

Subsequently, the hole is filled with a conductor, and the semiconductor is thinned by polishing and etching the bottom surface of the semiconductor substrate so that the conductor is exposed, thereby forming the penetration electrode 115.

However, in the conventional penetration electrode, there are problems caused by the method for manufacturing as follows.

As shown in FIG. 18, when a dry etching is carried out for forming the hole 106 in the semiconductor substrate 101, overhang sections 108a through 108c are also formed. This is because of a side-etch occurred while the etching. The overhang sections 108a through 108c have a larger bore diameter, as they are nearer to the lower layer. Namely, the overhang sections 108c nearer to the field oxide film 102 has the largest bore diameter, whereas the overhang section 108a nearer to the metal electrode pad 104 has the smallest bore diameter.

Specifically, as shown in FIG. 18, when the penetration electrode is formed in the metal electrode pad 104, the metal electrode pad 104 is side-etched while the dry etching of the masks 107, thereby forming the overhang section 108a. Also, the field oxide film 102 is side-etched, thereby forming the overhang section 108b. Furthermore, the semiconductor substrate 101 is side-etched, thereby forming the overhang section 108c. That is, in the semiconductor substrate during the manufacturing steps, the overhang sections 108a through 108c are formed in an upside-down staircase manner in an upper part of the hole 106 (on a side of the mask 0.107 of the semiconductor substrate 101). Also, in cases where the penetration electrode is formed in the field area, the field oxide film is side-etched while the dry etching of the mask, thereby forming an overhang section. Further, the semiconductor substrate is side-etched, thereby forming another overhang section. That is, the overhang sections are formed in like manner.

Even though an anisotropic etching method such as the RIE (Reactive Ion Etching) method is utilized for a method of dry etching, a side-etch cannot be perfectly prevented. This is because it is difficult to realize a perfect anisotorpic etching, although it is possible for an etching rate to be much greater in a perpendicular direction than in a horizontal direction. Particularly in cases where a hole has a depth falling within a range between several micrometers and several tens of micrometers, a side-etch under a field oxide film becomes too large to be ignored, thereby forming a large overhang section.

Because the etching mask is removed in the end of the etching process, the side-etch underneath the etching masks causes no problem. However, the side-etches in the other layers (such as the metal film, the field oxide film, the semiconductor substrate, or the like) cause various problems.

The first problem is that each coverage of the overhang sections deteriorates, when insulating the inside of the semiconductor substrate. On this account, it is difficult to perfectly insulate the inside of the hole, i.e., it is difficult to form the insulating film on the entire internal surface of the hole.

There are many methods for forming the insulating film in the hole, for example, a CVD (Chemical Vapor Deposition) method, a spray-coating method in which liquid of an organic insulating film material is used for spray-coating, a spin-coating method in which liquid of an organic insulating film material is used for spin-coating, or the like.

However, it is not realistic to utilize the CVD method because, even though an oxide film or a nitride film is formed in the hole as an insulating film by utilizing the CVD method, the oxide film or the nitride film does not cover sufficiently the internal surface of the hole on the account of the overhang sections in addition to a fundamental difficulty of forming a film in the hole. Therefore, as shown in FIG. 19, it is difficult to form the sufficient insulating film 109 under the existence of the overhang section 108c caused by side-etch.

It is also difficult to form a sufficient insulating film in the hole in cases where the spray-coating method or the spin-coating method, in both of which a liquid of an organic insulating material is used, is utilized. This is because the overhang sections prevent the liquid of the organic insulating material from fully spreading into the hole, thereby making it difficult for air bubble in the material to be removed

The second problem is that it is difficult to form a conductor in the hole, because of the overhang sections, after the insulating film is formed in the hole.

Indeed, the conductor can be formed in the hole (i) by forming a conductor film by carrying out sputtering or vapor deposition, (ii) by carrying out plating, or (iii) by filling an electrically conductive paste.

However, for example, even though the conductor is formed by carrying out the sputtering or the vapor deposition, the conductive film is not sufficiently formed to the depth of the hole because of the overhang sections. This is similar to the case of the forming of the insulating film in the hole. This arises a problem that electrical conduction of the penetration electrode is not ensured.

Also, electrical conduction of the penetration electrode is not ensured in cases where a conductor is formed in the hole by carrying out the plating, because of the overhang section. This is because a chemical cannot fully spreading into the hole or cannot fully circulate in the hole.

Also, electrical conduction of the penetration electrode is not ensured in cases where an electrically conductive paste is filled in the hole by carrying out a printing because of the overhang section. This is because the electrically conductive paste is not fully filled in the hole, thereby causing a void to remain in the hole.

### SUMMARY OF THE INVENTION

An object of the present invention is to provide (i) a semiconductor apparatus including a penetration electrode which ensures an electrical conductivity and (ii) a method for manufacturing the semiconductor apparatus.

To achieve the object, a semiconductor apparatus in accordance with the present invention includes: (i) a semiconductor substrate; (ii) a field oxide film formed in a surface of the semiconductor substrate, the field oxide film having an aperture section; (iii) an electrode formed on the field oxide film; and (iv) a penetration electrode electrically connected to the electrode via the aperture section of the field oxide film and via a hole formed in the semiconductor substrate, the hole being formed in the aperture section of the field oxide film, when perpendicularly viewing the semiconductor substrate.

According to the arrangement, no overhang of the field oxide film is formed in the hole formed in the semiconductor substrate. This ensures a good and desirable coverage in the hole, thereby providing a semiconductor apparatus having a penetration electrode which secures a good and desirable electric conduction. Incidentally, when intending to form a penetration electrode in a semiconductor-element-mounted area (active area), a circuit of the semiconductor apparatus has to be formed in an area where no penetration electrode is formed. This causes a circuit design of the semiconductor apparatus to be complicated and space that the circuit occupies to be bigger. On the contrary, according to the present apparatus, the penetration electrode is formed in the electrode pad as described above, thereby avoiding the occurrence of such a problem.

To achieve the object, according to the present invention, a method for manufacturing a semiconductor apparatus that includes (i) a field oxide film formed in a surface of a semiconductor substrate, (ii) an electrode formed on the field oxide film, and (iii) a penetration electrode that penetrates the field oxide film and the semiconductor substrate, respectively, and that is electrically connected to the electrode, comprising the steps of: (a) forming an aperture section in the field oxide film so that the semiconductor substrate is exposed in the aperture section; (b) forming a hole in an area of the semiconductor substrate, the area being exposed in the aperture section of the filed oxide film; (c) forming an insulating film on an internal surface of the hole, and (d) forming an electrically conductive layer on the insulating film formed, the step (c) and (d) forming the penetration electrode.

According to the method, since the hole is formed in the area of the semiconductor substrate, the area being exposed in the aperture section of the field oxide film, no overhang of the field oxide film is formed in the hole, thereby ensuring a good and desirable coverage of the insulating film and the electrically conductive film to be realized and formed in the hole. On this account, it is possible to form a semiconductor apparatus having a penetration electrode which ensures good and desirable insulation and electrical conduction with respect to a semiconductor substrate. Incidentally, when intending to form a penetration electrode in a semiconductor-element-mounted area (active area), a circuit of the semiconductor apparatus has to be formed in an area where no penetration electrode is formed. This causes a circuit design of the semiconductor apparatus to be complicated and space that the circuit occupies to be bigger. On the contrary, according to the present method, the penetration electrode is formed in the electrode pad as described above, thereby avoiding the occurrence of such a problem.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is a cross sectional view showing a semiconductor apparatus of an embodiment in accordance with the present invention.

FIG. 2 is a cross sectional view illustrating a step of a method for manufacturing the semiconductor apparatus of the embodiment of the present invention.

FIG. 3 is a cross sectional view illustrating another step of the method for manufacturing the semiconductor apparatus of the embodiment of the present invention.

FIG. 4 is a cross sectional view illustrating a further step of the production method for manufacturing the semiconductor apparatus of the embodiment of the present invention.

FIG. 5 is a cross sectional view illustrating still a further step of the method for manufacturing the semiconductor apparatus of the embodiment of the present invention.

FIG. 6 is a cross sectional view illustrating a yet step of the method for manufacturing the semiconductor apparatus of the embodiment of the present invention.

FIG. 7 is a cross sectional view illustrating yet another step of the method for manufacturing the semiconductor apparatus of the embodiment of the present invention.

FIG. 8 is a cross sectional view illustrating yet a further step of the method for manufacturing the semiconductor apparatus of the embodiment of the present invention.

FIG. 9 is a cross sectional view illustrating still another step of the method for manufacturing the semiconductor apparatus of the embodiment of the present invention.

FIG. 10 is a cross sectional view illustrating a modified example of the method of the semiconductor apparatus.

FIG. 11 is a cross sectional view of a chip-size-package (CSP) exemplifying the modified example of the semiconductor apparatus.

FIG. 12 is a cross sectional view illustrating a step of a method for manufacturing a semiconductor apparatus of another embodiment of the present invention.

FIG. 13 is a cross sectional view illustrating another step of the method for manufacturing the semiconductor apparatus of another embodiment of the present invention.

FIG. 14 is a cross sectional view illustrating a further step of the method for manufacturing the semiconductor apparatus of another embodiment of the present invention.

FIG. 15 is a cross sectional view illustrating still a further step of the method for manufacturing the semiconductor apparatus of another embodiment of the present invention.

FIG. 16 is a cross sectional view showing a semiconductor apparatus having a conventional penetration electrode.

FIG. 17 is a cross sectional view showing another semiconductor apparatus having a conventional penetration electrode.

FIG. 18 is a cross sectional view illustrating a step of a method for manufacturing a semiconductor apparatus having a conventional penetration electrode.

FIG. 19 is a cross section view illustrating another step of the method for manufacturing the semiconductor apparatus having the conventional penetration electrode.

### DESCRIPTION OF THE EMBODIMENTS

[First Embodiment]

The following description deals with a semiconductor apparatus of one embodiment of the present invention with references to figures.

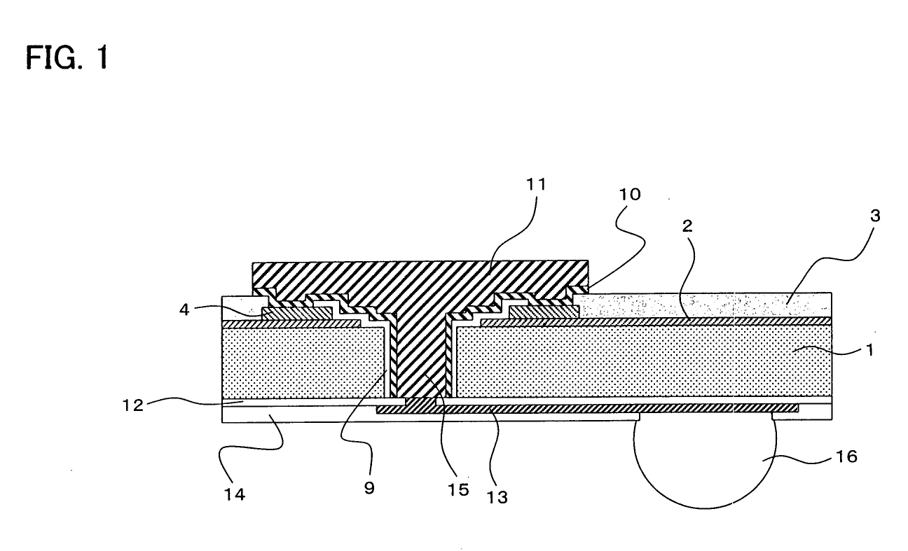

FIG. 1 is a cross sectional view of a semiconductor apparatus in accordance with the present embodiment. As shown in FIG. 1, in the semiconductor apparatus, indicated by a reference numeral 1 is a semiconductor substrate, indicated by a reference numeral 2 is a field oxide film, indicated by a reference numeral 3 is an insulating protective film, indicated by a reference numeral 4 is an electrode pad (electrode), indicated by a reference numeral 9 is an insulating film for insulating an internal surface of a hole, indicated by a reference numeral 10 is a seed metal (electrically conductive layer), indicated by a reference numeral 11 is a hole-filling section, indicated by a reference numeral 12 is an insulating film formed on a bottom surface of the semiconductor substrate 1, indicated by a reference numeral 13 is a rewiring metal layer (conductor layer), indicated by a reference numeral 14 is a protective layer (insulating layer) for protecting a rewired wire, indicated by a reference numeral 15 is a penetration electrode, and indicated by a reference numeral 16 is a lead-out electrode such as a solder ball. Note that a semiconductor element has already been provided on the semiconductor substrate 1.

In the semiconductor apparatus of the present embodiment, as shown in FIG. 1, the field oxide film 2, the insulating protective film 3, and the electrode pad 4 are formed on an upper surface of the substrate 1 made of, for example, silicon. Further, in the semiconductor apparatus, the insulating film 12 is formed on the bottom surface of the substrate 1. Further formed is the penetration electrode 15 that penetrates the electrode pad 4, the field oxide film 2, and the semiconductor substrate 1, respectively. Note that the penetration electrode 15 includes (i) the insulating film 9, formed in the hole of the semiconductor substrate 1, for insulating the internal surface of the hole, (ii) the seed metal layer 10 formed on the insulating film 9, and (iii) the hole-filling section 11.

Specifically, the electrode pad 4 has an aperture section extending to the field oxide film 2 in the thickness direction. The field oxide film 2 formed on the semiconductor substrate 1 has an aperture section extending to the semiconductor substrate 1 in the thickness direction. The aperture section of the field oxide film 2 is formed within an area of the field oxide film in the aperture section of the electrode pad 4. That is, when perpendicularly viewing from the side of the front face of the semiconductor substrate 1, the aperture section of the field oxide film 2 is formed within the aperture section of the electrode pad 4.

Further, the electrode pad 4, which serves as an input/output terminal for the semiconductor element (not shown) provided on the semiconductor substrate 1, is formed on the field oxide film 2. The electrode pad 4 is made of metal such as Al, Cu, AlSi, or AlCu. The insulating protective film 3 is formed on the field oxide film 2 and the electrode pad 4 so as to protect the field oxide film 2 and the electrode pad 4, respectively. Formed in the aperture section of the field oxide film 2 is the hole that penetrates the semiconductor substrate 1 in its thickness direction. An edge of the hole is within an area in the aperture section of the field oxide film 2 of the semiconductor substrate 1. That is, when perpendicularly viewing from the side of the front surface of the semiconductor substrate 1, the hole is formed within the aperture section of the field oxide film 2. Such an area the aperture section of the field oxide film 2 of the semiconductor substrate 1 is hereinafter referred to as a “penetration electrode forming area”. In the arrangement, when perpendicularly viewing from the side of the upper surface of the semiconductor substrate 1, the penetration electrode (hole) is formed within the area where the electrode pad 4 is formed.

Further, the insulating film 9 is formed so as to cover the internal surface of the hole, the penetration electrode forming area, a part of the field oxide film 2, and a part of the electrode pad 4, respectively. That is, the electrode pad 4 has an area which is not covered with the insulating film 9. The insulating film 9 and the electrode pad 4 (including the area which is not covered with the insulating film 9) are covered with the seed metal layer 10. Further, the hole is filled with the hole-filling section 11. The insulating film 9, the seed metal layer 10, and the hole-filling section 11 constitute the penetration electrode 15. The penetration electrode 15 is electrically connected to the electrode pad 4 via the seed metal layer 10.

Further, the insulating film 12 is formed on the bottom surface of the semiconductor substrate 1 for insulating the bottom surface of the semiconductor substrate 1. Formed on the insulating film 12 is the rewiring metal film 13, which serves as a wiring pattern. The rewiring metal film 13 is electrically connected to the penetration electrode 15 via an aperture of the insulating film 12. Further, the protective film 14, which protects the insulating film 12 and the rewiring metal film 13, is provided on the insulating film 12 and the rewiring metal film 13, respectively. The protective film 14 has an aperture section extending to the rewire metal film 13 in the thickness direction. In the aperture section of the protective film 14, a solder ball 16, which serves as a lead-out electrode, is provided, the solder ball 16 being connected to outside via the aperture section of the protective film 14.

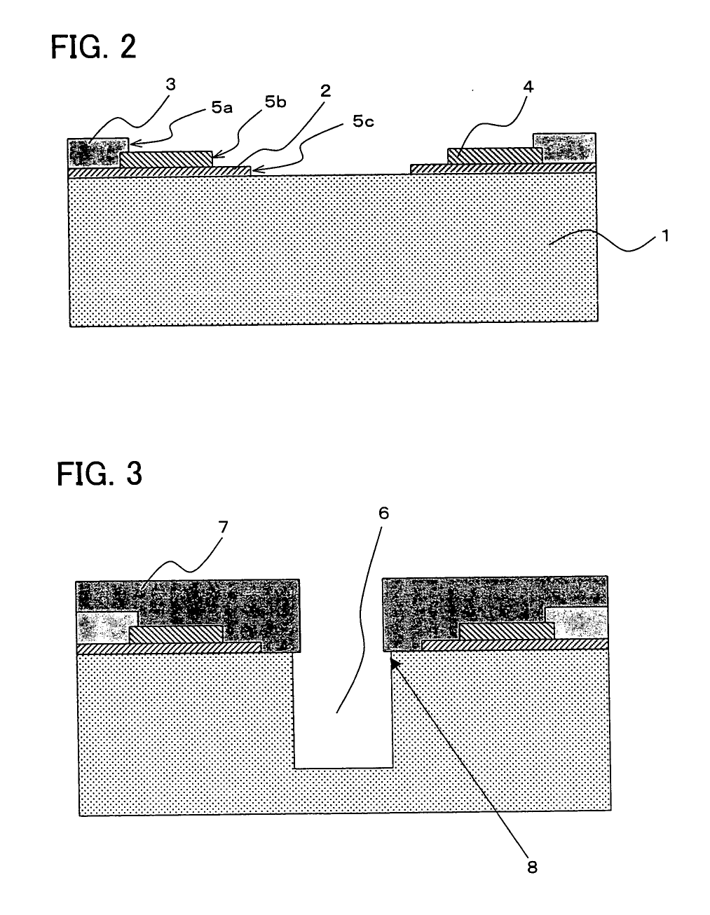

The following description deals with a method for manufacturing the semiconductor apparatus of the present embodiment with reference to FIG. 2 through FIG. 9.

First, a pre-processing step for forming an aperture section 5c in which a semiconductor substrate 1 is exposed is described with reference to FIG. 2.

Formed in the vicinity of an electrode pad 4 are a field oxide film 2, and an insulating protective film 3. In the pre-processing step, an electrode pad exposing aperture section (an aperture section of the insulating protective film) 5a is formed in the insulating protective film 3 so that the electrode pad 4 is exposed in the aperture. After that, in the electrode pad exposing aperture section 5a, a field oxide film exposing aperture section (an aperture section of the electrode pad (electrode)) 5b is formed in the electrode pad 4 so that the field oxide film 2 is exposed. Further, in the electrode pad exposing aperture section 5a, a semiconductor substrate exposing aperture section (an aperture section of the field oxide film) 5c is formed in the field oxide film 2 so that a semiconductor substrate 1 is exposed.

The pre-processing step can be easily done by carrying out a patterning beforehand so that the semiconductor substrate 1 is exposed in the electrode pad 4. This is similar to the forming of a dicing line during a step of forming a semiconductor element. Note that, when the aperture sections are not formed during the step of forming the semiconductor element, the aperture sections can be also easily formed as follows: after a resist mask is formed, etchings are carried out respectively to the insulating protective film 3, the electrode pad 4, and the field oxide film 2, in this order.

For example, when the pre-process step is carried out to a semiconductor substrate 1 in which an electrode designed for wire-bonding is formed, the following steps are carried out. After an electrode pad exposing aperture 5a is formed, a resist mask having an aperture section is formed on an electrode pad 4. The electrode pad 4 is removed by carrying out a dry etching, thereby forming a field oxide film exposing aperture section 5b. After that, the resist mask is removed, and another resist mask having an aperture section is formed on a field oxide film 2 in an area where the etching is carried out to the electrode pad 4 (field oxide film exposing aperture section 5b). The field oxide film 2 is removed by carrying out the dry etching, thereby forming a semiconductor substrate exposing aperture section 5c. After that, the resist mask is removed, and the upper surface of the semiconductor substrate is exposed.

As described above, even in a semiconductor substrate designed for wire-bonding, the semiconductor substrate exposing aperture 5c can be formed, although the number of the steps required therefor increases.

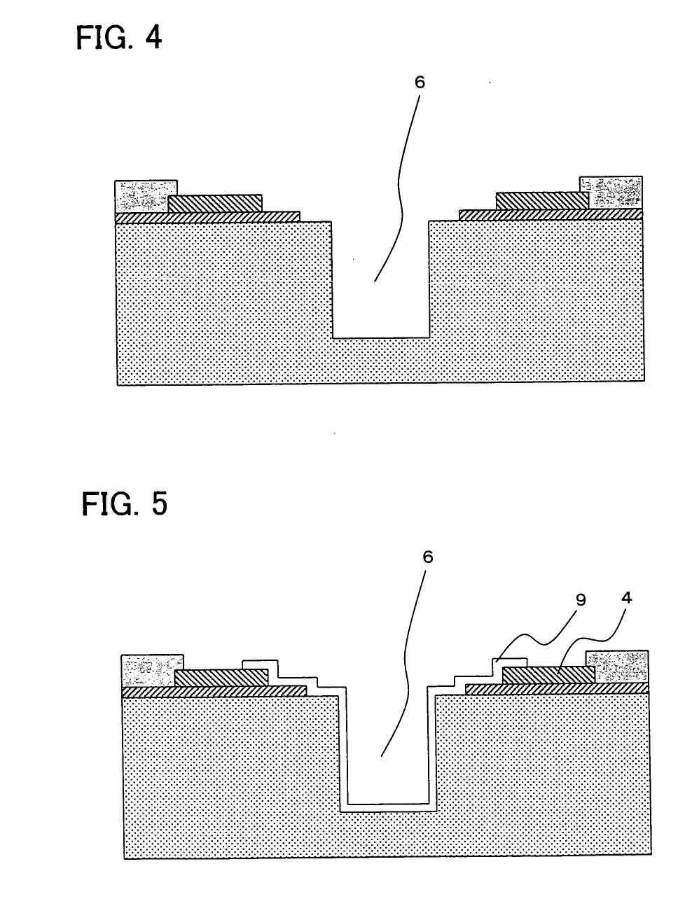

The following description deals with a step of forming a hole 6 in the semiconductor substrate 1 with reference to FIG. 3 and FIG. 4.

As shown in FIG. 3, in the step, formed is a resist mask 7 having an aperture section in an area of the semiconductor substrate 1, the area being exposed in the semiconductor substrate exposing aperture section 5c (a penetration electrode forming area). After that, the hole 6 is formed in the semiconductor substrate 1 by carrying out a dry etching, and the resist mask 7 is removed as shown in FIG. 4.

A bore diameter of the hole 6 at an edge of the upper surface of the semiconductor substrate 1 is selected in accordance with a size of a penetration electrode to be formed and/or a size of the semiconductor substrate exposing aperture section 5c. The resist mask 7 has a thickness required for carrying out the dry etching of the semiconductor substrate 1 to a predetermined depth of the hole 6. The resist mask 7 can be removed by a well-known method such as a treatment using an organic solvent or an ashing treatment.

The inventors of the present invention set (i) the bore diameter of the aperture of the resist mask 7 to 50-μm-square, and (ii) the thickness of the resist mask to 10 μm.

An etching selection ratio of the resist mask 7 to the semiconductor substrate 1 made of silicon was about 1:15, according to the dry etching apparatus that the present inventors used. Here, the target etching depth was set to about 120 μm, therefore, the thickness of the resist mask 7 could set to no less than 7 μm. Actually, the thickness of the resist mask 7 was set to 10 μm.

As the result, the hole 6 was successfully formed in the substrate 1 as shown in FIG. 3. However, in the hole 6, the resist mask 7 was slightly side-etched, so that a side-etched (overhang) section 8 was formed. The degree of a side-etching in the side-etched section 8 fell within a range between 0.5 μm and 1 μm. Even when an anisotropic dry etching is adopted, the side-etch is inevitable when deep etching is carried out. In view of the side-etch, the bore diameter of the aperture section of the resist mask 7 should be smaller than that of the semiconductor substrate exposing aperture section 5c. That is, the shortest distance between the perimeter of the aperture section of the resist mask 7 and the perimeter of the semiconductor substrate exposing aperture section 5c is preferably 0.5 μm, or more. More preferably, the shortest distance is 1.0 μm, or more.

Thus, there is no overhang in the hole 6 in the semiconductor substrate 1, and the hole 6 has a slightly tapered shape in which the bore diameter becomes larger toward the edge of the hole 6. Note that a taper angle in a sidewall of the hole 6 can be controlled to some extent by controlling an etching condition. In this case, the taper angle was controlled to fall within a range from 85° to 90°. The taper in the hole 6 does not cause any trouble in the following process as long as the hole 6 does not have an inverse tapered shape.

The following description deals with a step of forming a penetration electrode in the hole 6 in the semiconductor substrate 1, with reference to FIG. 5 through FIG. 7. In the step, a penetration electrode 15 is formed by forming an insulating film 9, a seed metal layer 10, and a hole-filling section 11 on the internal surface of the hole 6, in this order.

In the step of forming the penetration electrode, at the outset, the insulating film 9 is formed as shown in FIG. 5. The insulating film 9 is formed for insulating the internal surface of the hole 6 in the semiconductor substrate 1. When the hole is later filled with an electrically conductive paste or an insulating paste, the insulating film 9 prevents impurities of the electrically conductive paste or the insulating paste from diffusing in the semiconductor substrate 1.

The insulating film 9 can be formed by forming an oxide film such as SiO₂, or a nitride film such as SiN or AIN by utilizing the CVD method or the vapor deposition. Alternatively, the insulating film 9 can be formed by forming a film made of an insulating material such as an insulating resin with the use of carrying out a spray-coating, a spin-coating, a printing, or a vacuum printing. These methods ensure the insulating film 9 to be well formed, because there is no overhang section in an area near the upper surface of the semiconductor substrate 1—in other words, in an upper area of the hole 6. In addition, details about how to utilize the vacuum printing will be described later.

Here, a method for forming an oxide film made of SiO₂ by carrying out the CVD method is described as an example of forming the insulating film 9.

When the CVD method is carried out for forming an oxide film, the semiconductor substrate 1 is biased so as to draw SiO₂ into the hole 6, thereby forming the insulating film 9. Note that thickness of the insulating film 9 in the hole 6 falls within a range from ⅓ to ⅕ thinner than thickness of the oxide film on the semiconductor substrate 1.

The inventors of the present invention formed an oxide film whose thickness is 3 μm on the semiconductor substrate 1, thereby ensuring an insulating film 9, whose thickness falls within a range from 0.5 μm to 0.6 μm, to be formed in the hole 6.

Unnecessary part of the insulating film 9 on the electrode pad 4 is removed by carrying out an etching or the like, so that the electrode pad 4 is exposed. This secures a connection between a penetration electrode 15 to be formed and the electrode pad 4. The unnecessary part of the insulating film 9 may be removed, for example, as follows. A resist mask covering (i) the entire insulating film 9 in the hole 6, and (ii) a part of the electrode pad 4 is formed. After that, an exposed area in the insulating film 9 is removed by carrying out a dry etching or the like, and the resist mask is removed, thereby forming the insulating film 9 that covers (i) the internal surface of the hole 6 in the semiconductor substrate 1, (ii) the part of the upper surface of the semiconductor substrate 1 which is exposed in the semiconductor substrate exposing aperture section 5c, (iii) the part of the field oxide film 2 in the field oxide film exposing aperture section 5b, and (iv) a part of the electrode pad 4, respectively.

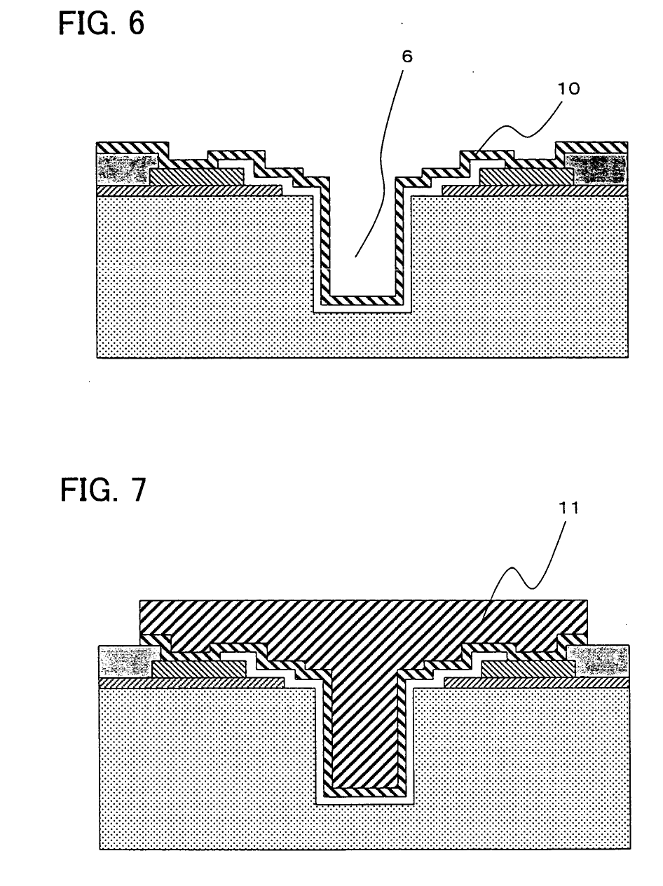

Subsequently, a seed metal layer (electrically conductive layer) 10 is formed on the insulating film 9 as shown in FIG. 6. The seed metal layer 10 can be formed by forming a conductor such as Ti, Cu, Al, or CuNi with the use of the sputtering method, the vapor deposition method, the CVD method, or the plating method. Alternatively, the seed metal layer 10 can be formed by forming an electrically conductive material such as an electrically conductive paste with the use of the spray-coating, the spin-coating, the printing, or the vacuum printing. These methods allow the seed metal 10 to be well formed because there is no overhang section in an area near the upper surface of the semiconductor substrate 1—in other words, in an upper area of the hole 6. Therefore, the seed metal layer 10 ensures an electrical conduction between the upper and bottom surfaces of the semiconductor substrate 1. Also, when the hole 6 is later filled with an electrically conductive paste or an insulating paste, the seed metal layer prevents impurities of the electrically conductive paste or the insulating paste from diffusing in the semiconductor substrate 1.

The inventors of the present invention formed a Ti layer and a Cu layer as the seed metal layer 10 by utilizing the sputtering method, the sputtering being carried out with respect to the upper surface of the semiconductor substrate 1. On the upper surface of the semiconductor substrate 1, the Ti layer having a thickness of 0.1 μm and the Cu layer having a thickness of 0.3 μm are formed, respectively. On the internal surface of the hole 6, the Ti layer and the Cu layer each having a thickness of around ⅓ to ⅕ of the Ti layer and the Cu layer on the upper surface of the semiconductor substrate 1.

Then, as shown in FIG. 7, the hole-filling section 11 is formed in the hole 6 where the insulating film 9 and the seed metal layer 10 are formed. The hole-filling section 11 is formed, for example, by applying an electrolytic plating to the hole 6, filling the hole 6 with an electrically conductive paste or an insulating paste, or the like.

Here, details about forming a hole-filling section 11 made of Cu by applying electrolytic Cu plating are described as an example of forming the hole-filling section 11.

A resist mask having an aperture is formed so that the seed metal layer 10 is exposed in the aperture. After that, electrolytic Cu plating is applied, thereby forming the hole-filling section 11.

After the hole-filling section 11 is formed, the resist mask is removed, and the hole-filling section is used as another mask. The seed metal 10, formed by the Ti layer and the Cu layer that have been exposed, are removed by carrying out an etching with the use of a chemical. On this account, the structure of the semiconductor apparatus shown in FIG. 7 is obtained.

It takes a long time for the electrolytic Cu plating to fill the hole 6 completely without any void. Therefore, in light of short-time processing, it is preferable to fill the hole 6 by printing an electrically conductive paste, thereby forming the hole-filling section 11. Furthermore, in cases where the seed metal 10 has a thin thickness (like the Ti layer of 0.1 μm and the Cu layer of 0.3 μm) as described above, a resistance of the penetration electrode becomes high because of thin seed metal 10. Therefore, by filling the hole 6 with an electrically conductive paste so that the hole-filling section 11 is formed, it is possible to reduce the resistance of the penetration electrode.

In cases where a resistance is necessary and sufficient, such a resistance being obtainable by forming an Al layer having a thickness of not less than 1 μm based on the sputtering method or other method, it is not necessary to separately form a hole-filling section 11. However, note that it is preferable to form the hole-filling section 11 by filling the hole 6 with an insulating paste so that the hole 6 is reinforced. That is, the hole-filling section 11 allows the strength of the penetration electrode to increase, and allows the strength of the semiconductor apparatus to increase.

Further, it is preferable that the electrically conductive paste and the insulating paste are printed by using the vacuum printing method. The vacuum printing method ensures the pastes to be filled even in a minute and deep hole.

The vacuum printing method includes the steps of (i) printing a paste material in a hole and pushing the paste material into the hole under vacuum, and (ii) drawing the paste material into the hole in accordance with differential pressure between the inside of the hole and the outside of the hole, the differential pressure being caused by increasing pressure after the printing. The pressure obtained after the printing may be higher than the normal pressure. The degree of vacuum in the vacuum printing method normally falls within a range from 1.333 Pa to 3.9 kPa, and preferably from 13.3 Pa to 666.6 Pa. It is preferable that the degree of viscosity of the paste material normally falls within a range from 20 Pa·s to 200 Pa·s.

Especially in cases where a paste material is filled in a hole having a large aspect ratio, it is possible to fully fill such a hole with the paste by carrying out the vacuum printing more than once. This permits avoiding that the bottom part receives insufficient amount of paste.

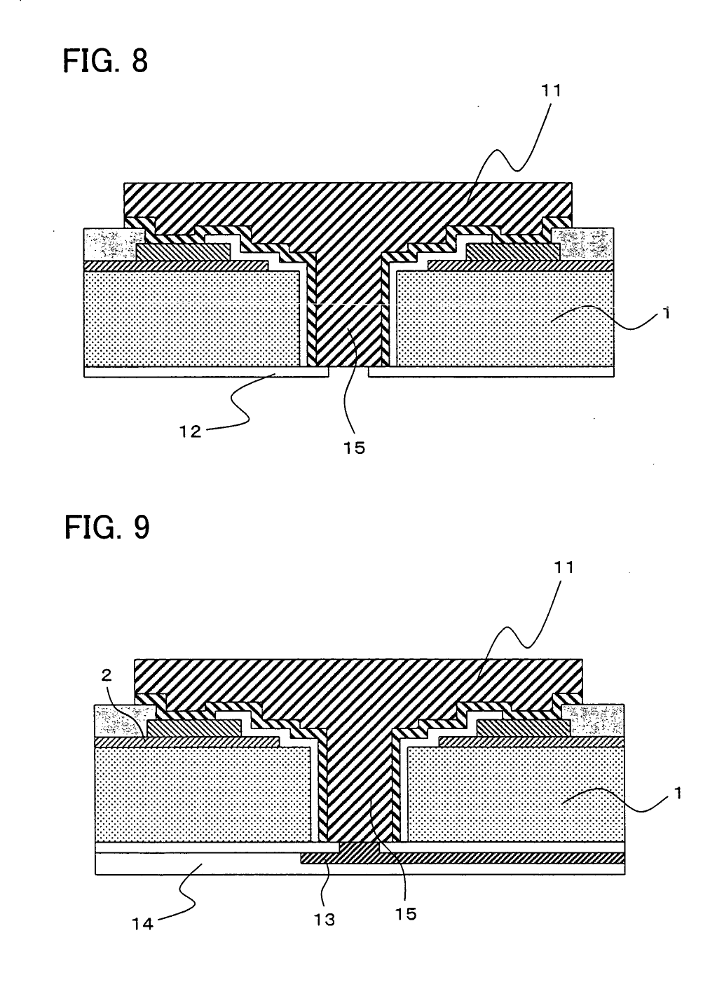

The following description deals with a post-process step of causing the penetration electrode 15 to be electrically connected to the bottom surface of the semiconductor substrate 1, with reference to FIG. 8 and FIG. 9. Well known methods can be used for the post-process step. An example of the conventional methods is described here.

First, a penetration electrode is exposed by grinding the bottom surface of a semiconductor substrate 1 as shown in FIG. 8. The grinded surface may be improved by polishing or etching in accordance with the need.

The inventors of the present invention had set the depth of the hole 6 (the length of the penetration electrode 15) to 120 μm. Therefore, the inventors of the present invention grinded the bottom surface of the semiconductor substrate 1 until thickness of the semiconductor substrate becomes 100 μm, thereby allowing the penetration electrode 15 to be exposed.

Then, an insulating film 12 is formed on the polished bottom surface of the semiconductor substrate 1 so that a leakage between the penetration electrode 15 and the semiconductor substrate 1 is prevented. The insulating film 12 may be an oxide film such as SiO₂ or a nitride film such as SiN or AlN that are formed based on the CVD method. Alternatively, the insulating film 12 may be formed by applying an insulation resin, or by other methods.

Thereafter, an aperture section is formed in the insulating film 12 so that the penetration electrode 15 is exposed. The aperture section will be formed as follows. A resist mask is formed on the insulating film 12, and the aperture section of the insulating film 12 is formed by carrying out a dry etching to the insulating film 12. Alternatively, the aperture section, in which the penetration electrode 15 is exposed, can be formed in a photo step with ease, in cases where the insulating film 12 is made of a photosensitive insulating resin. Thus, the penetration electrode 15 is completed; the upper surface of the semiconductor substrate 1 and the bottom surface of the semiconductor substrate 1 are electrically connected with each other. Note that, in cases where an insulating material is used for the hole-filling section 11, an aperture section should be formed so that the seed metal layer 10 is exposed.

Subsequently, as shown in FIG. 9, carried out is a rewiring step of forming a lead-out electrode for the penetration electrode 15. In the rewiring step, a rewiring metal layer (conductor layer) 13 is formed on the insulating film 12, and then, an insulating layer 14 is formed on the rewiring metal layer 13. After that, an aperture, in which the rewiring metal layer 13 is exposed, is formed in the insulating layer 14. Finally, formed is a lead-out electrode, such as a solder ball, which is connected to the rewiring metal layer 13 exposed in the aperture (see FIG. 1). On this account, in the bottom surface of the semiconductor substrate 1, the semiconductor apparatus can be electrically connected to outside via the penetration electrode 15, the rewiring metal layer 13, and the lead-out electrode. Note that a patterning of the rewiring metal layer 13 allows the lead-out electrode to be formed in an arbitrary position in the bottom surface of the semiconductor substrate 1.

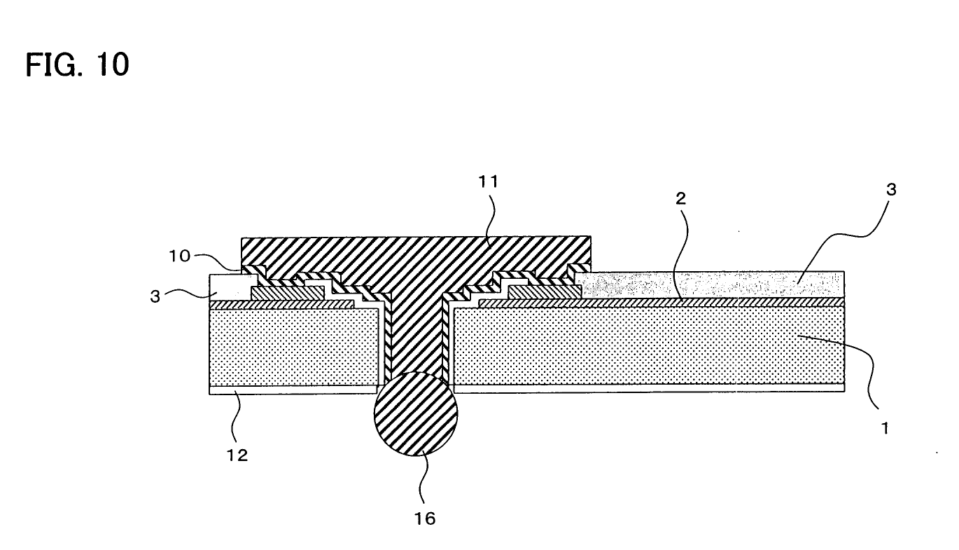

Alternatively, a lead-out electrode (input/output terminal) 16 such as a solder ball may be formed directly to the penetration electrode 15 without forming the rewiring metal layer 13, as shown in FIG. 10.

As described above, according to the method for manufacturing the semiconductor apparatus, the penetration electrode 15 can be formed in the semiconductor substrate 1. In the penetration electrode 15, there is no overhang of the field oxide film 2 in the aperture section of the hole formed in the upper surface of the semiconductor substrate 1, thereby ensuring the insulating film 9 and the seed metal layer 10 to be formed on the internal surface of the hole. That is, in the semiconductor apparatus, the insulating film 9 ensures an insulation of the penetration electrode 15 from the semiconductor substrate 1. Further, the seed metal layer 10 ensures an electrical conduction between the upper and bottom surfaces of the semiconductor substrate 1. Therefore, the insulating film 9 and the seed metal layer 10 allow the penetration electrode 15 to have higher reliability. Furthermore, the penetration electrode 15 is formed so as to penetrate the electrode pad 4, thereby allowing the semiconductor apparatus to be downsized. In cases where the penetration electrode 15 is formed in a semiconductor-element-mounted area (active area), a circuit of the semiconductor apparatus has to be formed in an area where the penetration electrode 15 is not formed. This causes a circuit design to be complicated, and causes space that the circuit occupies to be bigger. On the contrary, no such problems occur by forming the penetration electrode 15 in the field area, especially in the electrode pad 4 as described above.

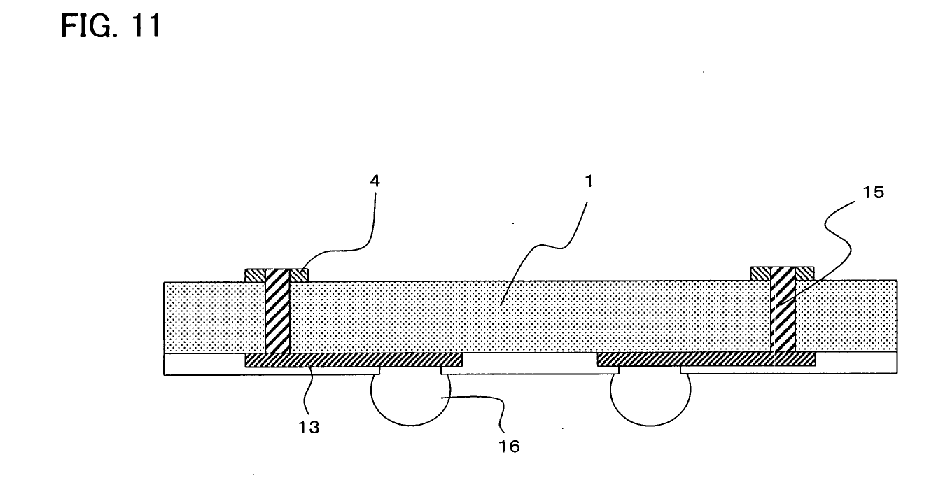

The following description deals with an example of a chip-size-package (CSP) semiconductor apparatus, which is fabricated in accordance with the aforementioned method for manufacturing a semiconductor apparatus, with reference to FIG. 11.

As shown in FIG. 11, in the CSP semiconductor apparatus, an electrode pad 4 of the semiconductor apparatus is connected to a lead-out electrode 16 via a penetration electrode 15 and a rewiring metal layer 13, thereby allowing the CSP semiconductor apparatus to be dramatically compact and thin. The method ensures the good and desirable formation of the penetration electrode, thereby realizing a CSP semiconductor apparatus, whose size is the actual size of the chip, without using any wires. That is, a lead-out wire has been provided via a wire in a conventional semiconductor apparatus. On the contrary, in the CSP semiconductor apparatus, as is clear from FIG. 11, in the upper surface of the semiconductor apparatus, the solder ball 16, served as a lead-out electrode, is provided via the penetration electrode 15. On this account, the size of the CSP semiconductor apparatus is the actual size of the chip.

Further, a high-density multi-chip module can be realized by layering a plurality of the CSP semiconductor apparatuses.

[Second Embodiment]

The following description deals with another embodiment of the present invention with reference to the figures. For convenience of description, materials having the same functions as those shown in the drawings pertaining to the foregoing First Embodiment will be given the same reference symbols, and explanation thereof will be omitted here. In the present embodiment, a penetration electrode is formed in a different area from the area where the penetration electrode is formed in the First Embodiment. The present embodiment shows an example of the following semiconductor apparatus. According to the apparatus, a penetration electrode is formed in a field area of a semiconductor substrate on which a semiconductor element is provided, and the penetration electrode is connected to an electrode pad which serves as an input/output terminal. Note that the word “field area” means an area, where no semiconductor element is provided, in the upper surface of the semiconductor substrate.

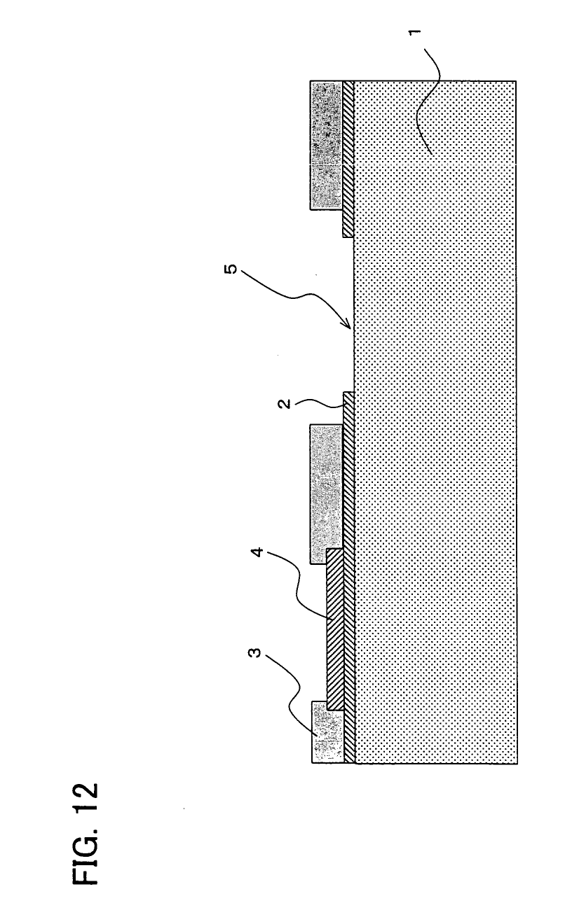

The following description deals with a method for manufacturing a semiconductor apparatus of the present embodiment with reference to FIG. 12 through FIG. 15.

Shown in FIG. 12 is a typical structure of periphery of an electrode pad on a semiconductor substrate. A field oxide film 2 is formed on a semiconductor substrate 1. On the field oxide film 2, an electrode pad 4 is formed. On the field oxide film 2 and the electrode pad 4, an insulating productive film 3 is formed. Further, in the insulating protective film 3, an aperture section, in which the electrode pad 4 is exposed, is formed. In the insulating protective film 3, an aperture section, in which the field oxide film 2 is exposed, is also formed. Further, in the field oxide film 2, an aperture section, in which the upper surface of the semiconductor substrate 1 is exposed, is formed so as to expose. The aperture section in the field oxide film 2 is an area 5 where a penetration electrode is formed. As described above, in the present embodiment, no field oxide film exposing aperture section is formed in the electrode pad 4, unlike in the First Embodiment, and the electrode pad 4 is formed in a different area from the penetration electrode forming area 5.

Note that the semiconductor substrate exposing aperture section (the penetration electrode forming area 5) and the field oxide film exposing aperture section can be easily formed by carrying out a patterning beforehand in a similar manner to a manner in which a dicing line is formed in a step of forming a semiconductor element. When the semiconductor substrate exposing aperture section (the penetration electrode forming area 5) and the field oxide film exposing aperture section are not formed in the semiconductor element forming step, the aperture sections can be formed as follows. After a resist mask is formed, etchings are sequentially carried out to the insulating protective film 3 and field oxide film 2, respectively.

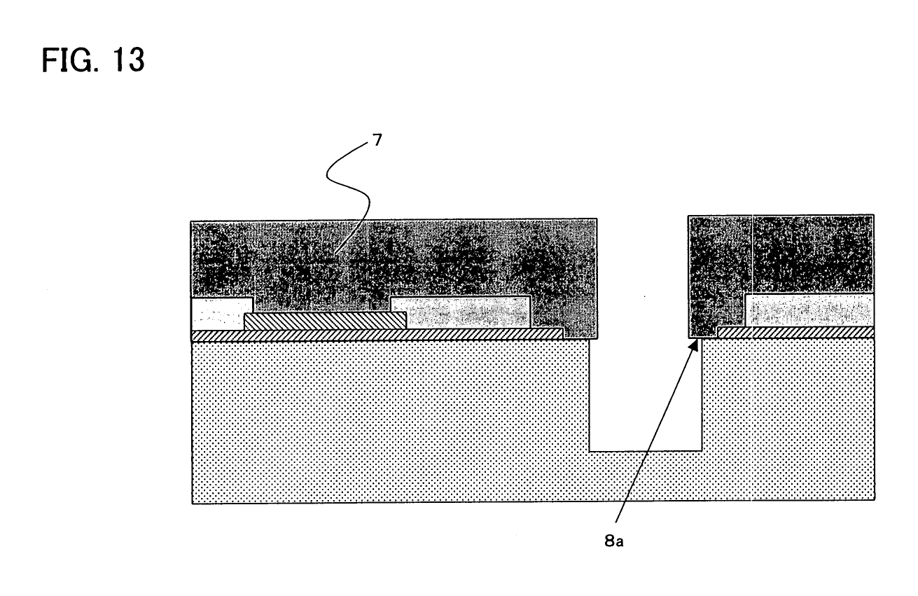

As shown in FIG. 13, in the method for manufacturing a semiconductor apparatus of the present embodiment, formed is a resist mask 7 having an aperture section in the penetration electrode forming area 5 of the semiconductor substrate shown in FIG. 12. A thickness of the resist mask 7 is not limited to a specified one as long as the resist mask 7 is thick enough for forming a hole having a predetermined depth, the hole being formed by carrying out a dry etching or the like. After that, a hole 6 is formed by carrying out a dry etching or the like. A bore diameter of an aperture of the hole 6 in the upper surface of the semiconductor substrate 1 can be set to such a size as to be suitable for (i) a size of a penetration electrode to be formed, and/or (ii) a size of the penetration electrode forming area 5.

The inventors of the present invention formed the hole 6 so as to set (i) the bore diameter of the aperture of the resist mask 7 to 10-μm-square, and (ii) the thickness of the resist mask 7 to 7 μm. As described in the First Embodiment, an etching selection ratio of the resist mask to the semiconductor substrate 1 made of silicon was about 1:15 in the dry etching apparatus that the present inventors used. Here, a target depth of the etching was set to about 70 μm, therefore the thickness of the resist mask 7 should be not less than 5 μm. In this case, the thickness of the resist mask 7 was set to 7 μm. The semiconductor substrate 1 is slightly side-etched while the dry etching of the resist mask 7 (a side-etched section 8a). According to the measurement, the length of the side-etched section 8a fell within a range from 0.3 μm to 1 μm. In contrast, there is no side-etched section formed in the semiconductor substrate 1 while the dry etching of the oxide film 2.

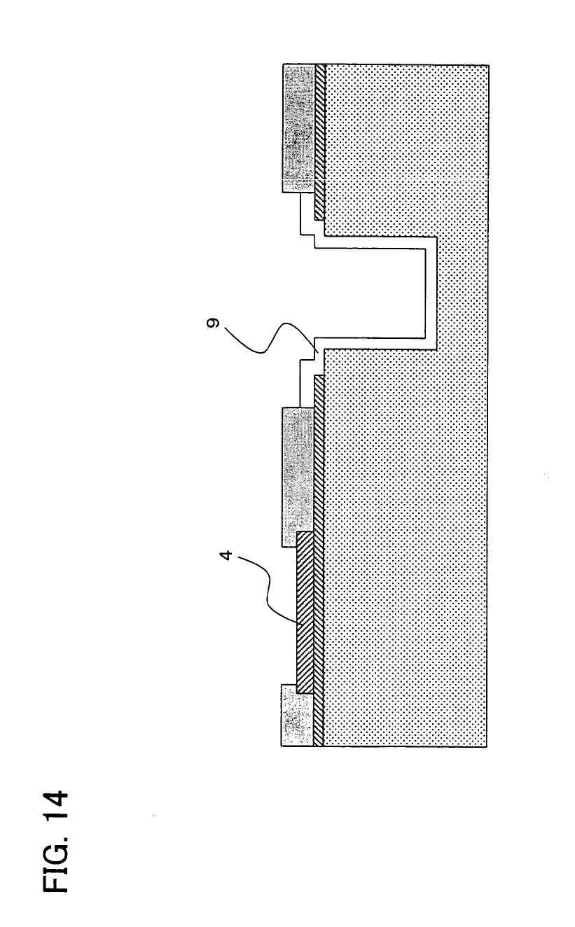

Subsequently, the resist mask 7 was removed as shown in FIG. 14. After that, an oxide film (an insulating film 9) made of SiO₂ was formed by utilizing the CVD method so as to insulate the inside of the hole 6, the insulating film 9 being formed in a similar manner to the First Embodiment. The insulating film 9 is ensured to be formed in good and desirable conditions because there is no overhang section of the field oxide film 2 in the aperture section of the hole 6.

The inventors of the present invention formed an oxide film whose thickness is 1.5 μm on the upper surface of the semiconductor substrate 1. This allows the oxide film whose thickness falls within a range from 0.3 μm to 0.5 μm to be formed on the internal surface of the hole 6, the oxide film serving as the insulating film 9.

Subsequently, the oxide film formed on the electrode pad 4 and the insulating protective film 3 that require no oxide film is removed so that a connection is secured between the electrode pad 4 and the penetration electrode to be later formed. It is possible to remove the oxide film from the electrode pad 4 and the insulating protective film 3, respectively, for example, as follows: A photo resist is formed, and an exposure and a development are carried out, and then, a dry etching is carried out with respect to the oxide film. That is, the insulating film 9 is formed by carrying out a dry etching to the upper surface of the semiconductor substrate 1 excluding (i) the field oxide film 2 which is exposed in the field oxide film exposing aperture section, (ii) the upper surface of the semiconductor substrate 1 which is exposed in the semiconductor substrate exposing aperture section, and (iii) the inside of the hole 6. After the dry etching, the photo resist is removed.

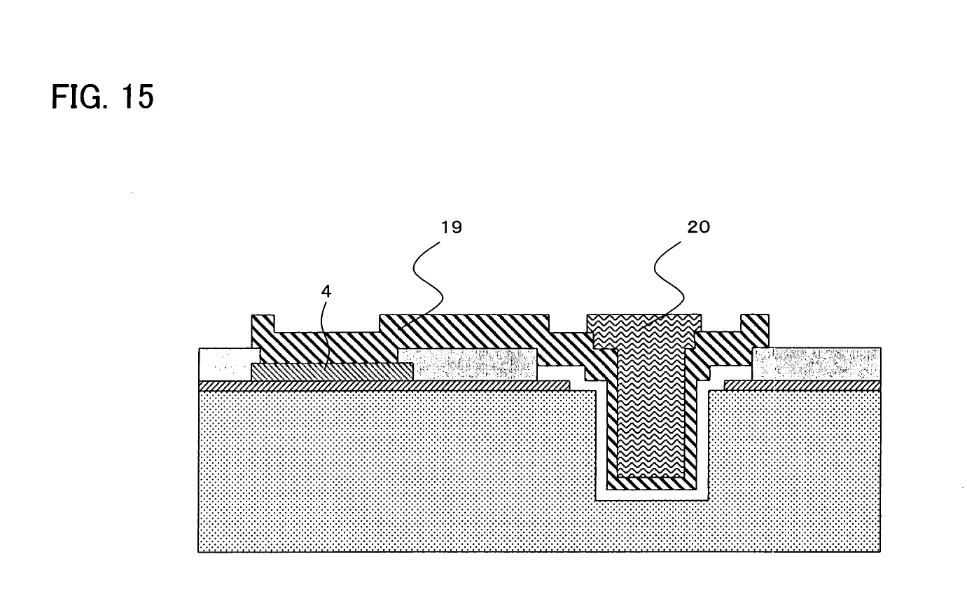

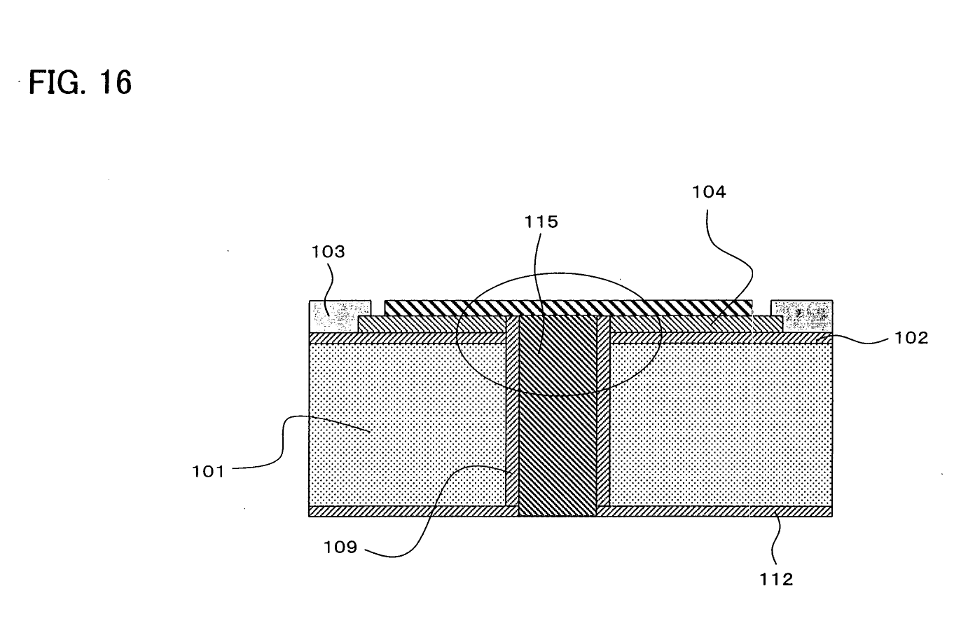

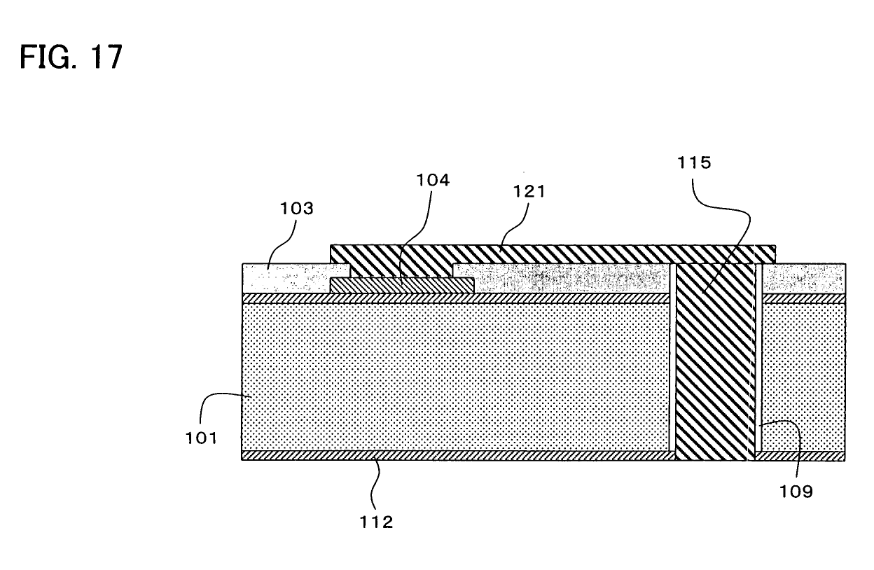

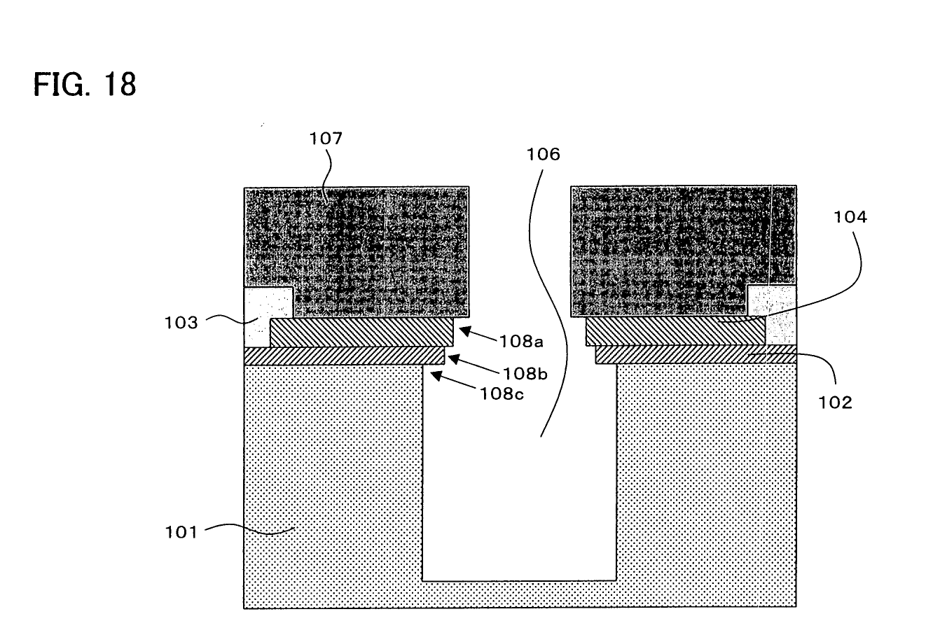

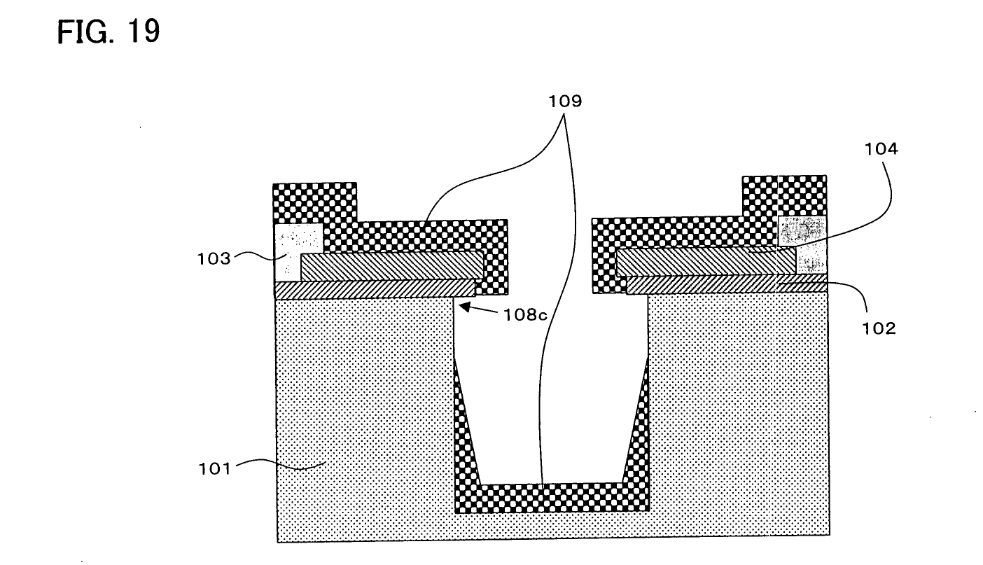

Subsequently, as shown in FIG. 15, an electrically conductive layer 19 is formed so as to ensure an electrical connection between the penetration electrode and the electrode pad 4, the electrically conductive layer 19 extending to the electrode pad 4 from the inside of the hole 6. Note that the electrically conductive layer 19 is a constituting component of the penetration electrode.

The electrically conductive layer 19 can be formed, for example, as follows: An Al layer is formed in the upper surface of the semiconductor substrate 1 by utilizing the sputtering method. Thereafter, a patterning is carried out to the Al layer by etching the Al layer so that the Al layer is connected to the electrode pad 4 which serves as an input/output terminal, thereby forming the electrically conductive layer 19. The electrically conductive layer 19 is ensured to be formed in good and desirable conditions because there is no overhang section of the field oxide film 2 in the aperture section of the hole 6, the aperture section of the hole 6 being formed in the upper surface of the semiconductor substrate 1.

Subsequently, a hole-filling section 20 is formed by filling the hole 6 with an electrically conductive paste, thereby forming the penetration electrode. That is, the electrically conductive paste can be filled in the hole 6 by (i) forming a screen mask that has an aperture so that the hole 6 is exposed, and (ii) printing the electrically conductive paste with the use of screen mask. In cases where the electrically conductive layer 19 gives an appropriate resistance to the penetration electrode, the hole-filling section 20 is not necessarily provided. However, even in such cases, it is preferable to fill the hole 6 with an insulating paste or the like so as to form the hole-filling section 20. This allows the hole-filling section 20 to reinforce the inside of the hole 6. On this account, a good and desirable penetration electrode can be realized.

In the present embodiment, it is possible to print the electrically conductive paste in the hole 6 without forming air in the electrically conductive paste. That is, no void is formed in the electrically conductive paste, thereby obtaining a good and desirable penetration electrode.

The inventors of the present invention formed an Al film whose thickness was 1 μm in the upper surface of the semiconductor substrate 1 by utilizing the sputtering method, the Al film serving as the electrically conductive layer 19. On this occasion, the Al film formed on the internal surface of the hole 6 has a thickness falling in a range from ⅓ μm to ⅕ μm. The thickness of the Al film was so thin that the Al film seems not to function appropriately as the electrically conductive layer 19. Therefore, an electrically conductive paste 20 was filled in the hole 6 by carrying out a vacuum printing, thereby forming a penetration electrode. In this case, the hole 6 could not be filled by carrying out the printing one time because the depth of the hole 6 was longer than the width of the hole 6, therefore the printing was carried out four or five times.

The similar process steps to the First Embodiment can be applied to the subsequent steps in the Second Embodiment.

According to the method for manufacturing the semiconductor apparatus, it is possible to form the penetration electrode in the semiconductor substrate. Since there is no overhang of the field oxide film in the aperture section of the hole formed in the upper surface of the semiconductor substrate 1, it is possible to provide the semiconductor apparatus having the highly-reliable penetration electrode which ensures (i) electrical insulation from the semiconductor substrate, and (ii) electrical conduction to the electrode pad.

According to the present invention, in a semiconductor apparatus, an electrode pad is formed on an oxide film on the upper surface of a semiconductor substrate, a penetration electrode is formed so as to bridge the upper surface and the bottom surface of the semiconductor substrate, and the electrode pad and the penetration electrode are connected with each other. Because the penetration electrode is formed within an aperture section of the field oxide film on the upper surface of the semiconductor substrate, it is possible to eliminate any overhang formed in the upper area of the aperture section where the penetration electrode is formed. This allows good and desirable coverage of an insulating film and an electrically conductive film to be realized and formed in the penetration electrode. This ensures a hole-filling section to be sufficiently formed, thereby obtaining a highly-reliable penetration electrode.

Further, when the vacuum printing method is adopted so as to form the insulating layer and the electrically conductive layer in the inside of the penetration electrode, it is possible to realize the good and desirable coverage of the insulating film and the electrically conductive film, and it is also possible to form a better and desirable hole-filling section without any void even in a small hole whose width is lopm. On this account, a dramatically highly-reliable penetration electrode can be obtained.

The present invention is not limited to the foregoing respective embodiments, but may be altered within the scope of the claims. An embodiment based on any combination of technical means disclosed in different embodiments is encompassed in the technical scope of the present invention.

To solve the foregoing problems, a semiconductor apparatus of the present invention includes (i) a semiconductor substrate; (ii) a field oxide film formed in a surface of the semiconductor substrate, the field oxide film having an aperture section; (iii) an electrode formed on the field oxide film; and (iv) a penetration electrode electrically connected to the electrode via (a) the aperture section of the field oxide film and (b) a hole formed in the semiconductor substrate, the hole being formed in the aperture section of the field oxide film, when perpendicularly viewing the semiconductor substrate.

According to the arrangement, no overhang of the field oxide film is formed in the hole formed in the semiconductor substrate. This ensures a good and desirable coverage in the hole, thereby providing a semiconductor apparatus having a penetration electrode which secures a good and desirable electric conduction. Incidentally, when intending to form a penetration electrode in a semiconductor-element-mounted area (active area), a circuit of the semiconductor apparatus has to be formed in an area where no penetration electrode is formed. This causes a circuit design of the semiconductor apparatus to be complicated and space that the circuit occupies to be bigger. On the contrary, according to the present apparatus, the penetration electrode is formed in the electrode pad as described above, thereby avoiding the occurrence of such a problem.

In addition to the arrangement of the semiconductor apparatus in accordance with the present invention, it is preferable that the penetration electrode is formed in a field area of the surface of the semiconductor substrate.

Note that the word “field area” means an area where no semiconductor element is formed in the semiconductor substrate. According to the arrangement, the penetration electrode allows the semiconductor apparatus to appropriately function.

In addition to the arrangement of the semiconductor apparatus in accordance with the present invention, it is preferable that the electrode has an aperture section and the penetration electrode is connected to the electrode in the aperture section of the electrode.

According to the arrangement, since the penetration electrode is connected to the electrode in the aperture section of the electrode, it is possible to reduce an area where the penetration electrode is formed, thereby downsizing the semiconductor apparatus.

In addition to the arrangement of the semiconductor apparatus in accordance with the present invention, it is preferable that the aperture section of the field oxide film is formed in the aperture section of the electrode, when perpendicularly viewing the semiconductor substrate.

According to the arrangement, no overhang of the electrode is formed in the aperture section of the field oxide film, thereby realizing and forming a penetration electrode having a good and desirable coverage in the aperture section of the field oxide film.

In addition to the arrangement of the semiconductor apparatus in accordance with the present invention, it is preferable that the penetration electrode includes an insulating film formed on an internal surface of the hole.

According to the arrangement, the insulating film is formed in the hole having no overhang, thereby ensuring a good and desirable coverage in the hole. The insulating film permits electrical insulation of the penetration electrode with respect to the semiconductor substrate, accordingly. Further, for example, in cases where an electrically conductive paste or an insulating paste is filled in the hole of the penetration electrode, the provision of the insulating film prevents an impurity of the electrically conductive paste or the insulating paste from dispersing in the semiconductor substrate.

In addition to the arrangement of the semiconductor apparatus in accordance with the present invention, it is preferable that the penetration electrode includes an electrically conductive layer on the insulating film that is formed on the internal surface of the hole.

According to the arrangement, the electrically conductive layer is formed in the hole having no overhang, thereby providing a good and desirable coverage in the hole. On this account, this electrically conductive layer secures electrical conduction in the penetration electrode. Incidentally, in cases where an electrically conductive paste or an insulating paste is later filled in the hole of the penetration electrode, the electrically conductive layer can prevent impurities of the electrically conductive paste or the substrate.

In addition to the arrangement of the semiconductor apparatus in accordance with the present invention, it is preferable that the penetration electrode includes a hole-filling section formed in the hole.

According to the arrangement, since the provision of the hole-filling section avoids that the hole is void, it is possible to improve the strengths of the penetration electrode and the strength of the semiconductor apparatus, respectively. Note that the hole-filling section may be made of an insulating material or an electrically conductive material. When the hole-filling section is made of an electrically conductive material, the electrical conduction in the penetration electrode can become better and more desirable.

In view of the foregoing problem, according to the present invention, a method for manufacturing a semiconductor apparatus that includes (i) a field oxide film formed in a surface of a semiconductor substrate, (ii) an electrode formed on the field oxide film, and (iii) a penetration electrode that penetrates the field oxide film and the semiconductor substrate, respectively, and that is electrically connected to the electrode, comprising the steps of: (a) forming an aperture section in the field oxide film so that the semiconductor substrate is exposed in the aperture section; (b) forming a hole in an area of the semiconductor substrate, the area being exposed in the aperture section of the filed oxide film; (c) forming an insulating film on an internal surface of the hole, and (d) forming an electrically conductive layer on the insulating film formed, the steps (c) and (d) forming the penetration electrode.

According to the method, since the hole is formed in the area of the semiconductor substrate, the area being exposed in the aperture section of the field oxide film, no overhang of the field oxide film is formed in the hole, thereby ensuring a good and desirable coverage of the insulating film and the electrically conductive film to be realized and formed in the hole. On this account, it is possible to form a semiconductor apparatus having a penetration electrode which ensures good and desirable insulation and electrical conduction with respect to a semiconductor substrate. Incidentally, when intending to form a penetration electrode in a semiconductor-element-mounted area (active area), a circuit of the semiconductor apparatus has to be formed in an area where no penetration electrode is formed. This causes a circuit design of the semiconductor apparatus to be complicated and space that the circuit occupies to be bigger. On the contrary, according to the present method, the penetration electrode is formed in tLe field area, especially in the electrode pad as described above, thereby avoiding the occurrence of such a problem.

In addition to the method of the semiconductor apparatus, it is preferable that the step (c) includes the step of (e) printing an insulating material under a certain air pressure so that the hole is covered, and then increasing the air pressure more than the certain air pressure so that a film made of the insulating material is formed on the internal surface of the hole.

According to the arrangement, since there is no overhang in the hole and the vacuum printing is adopted, it is possible to form an insulating film that has better and more desirable coverage. Further, even in cases where the hole is very small, the adoption of the vacuum printing ensures a film made of insulating material to be formed, thereby securing a good and desirable insulating film to be formed in the hole.

In the method for manufacturing the semiconductor apparatus of the present invention, it is preferable that the vacuum printing step is repeated more than once.

According to the method, by repeating the vacuum printing more than once, it is possible to form a film made of an insulating material in the hole without forming any void.

In the method for manufacturing the semiconductor apparatus of the present invention, it is preferable that the step (d) includes the step of (f) printing an electrically conductive material under a certain air pressure so that the hole is covered, and then increasing the air pressure more than the certain air pressure so that a film made of the electrically conductive film is formed on the internal surface of the hole.

According to the method, since there is no overhang in the hole and the vacuum printing is adopted, it is possible to form an electrically conductive film that has better and more desirable coverage. Further, even in cases where the hole is very small, the adoption of the vacuum printing ensures a film made of an electrically conductive material to be formed, thereby securing a good and desirable electrically conductive film to be formed in the hole.

In the method for manufacturing the semiconductor apparatus of the present invention, it is preferable that the vacuum printing step is repeated more than once.

According to the method, by repeating the vacuum printing more than once, it is possible to form a film made of an electrically conductive material in the hole without forming any void.

In addition to the steps of the method, it is preferable to further include the step of (g) forming a hole-filling section in the hole, the step (g) including the step of (h) printing an insulating material or an electrically conductive material under a certain air pressure so that the hole is covered, and then increasing the air pressure more than the certain air pressure so that the hole is filled with the insulating material or the electrically conductive material.

According to the method, since there is no overhang in the hole and the vacuum printing is adopted, it is possible to fill the hole with the insulating material or the electrically conductive material without forming any void. Further, even in cases where the hole is very small, the vacuum printing ensures a film made of an insulating material or an electrically conductive material to be formed, thereby permitting of filling the insulating material or the electrically conductive material in the hole. It is possible to form a good and desirable hole-filling section.

In the method for manufacturing the semiconductor apparatus of the present invention, it is preferable that the step (h) is repeated more than once so as to fill the hole with the insulating material or the electrically conductive material.

According to the method, by repeating the vacuum printing more than once, it is possible to fill the hole with the insulating material or the electrically conductive material without forming any void.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A semiconductor apparatus, comprising:
a semiconductor substrate;
a field oxide film formed in a surface of the semiconductor substrate, the field oxide film having an aperture section;
an electrode formed on the field oxide film; and
a penetration electrode electrically connected to the electrode via the aperture section of the field oxide film and via a hole formed in the semiconductor substrate,
the hole being formed in the aperture section of the field oxide film, when perpendicularly viewing the semiconductor substrate.

2. The penetration electrode as set forth in claim 1, wherein:
the penetration electrode is formed in a field area of the surface of the semiconductor substrate.

3. The penetration electrode as set forth in claim 1, wherein:
the electrode has an aperture section,
the penetration electrode is connected to said electrode in the aperture section of the electrode.

4. The penetration electrode as set forth in claim 3, wherein:
the aperture section of the field oxide film is formed in the aperture section of the electrode, when perpendicularly viewing the semiconductor substrate.

5. The semiconductor apparatus as set forth in claim 1, wherein:
the penetration electrode includes an insulating film formed on an internal surface of the hole.

6. The semiconductor apparatus as set forth in claim 5, wherein:
the penetration electrode includes an electrically conductive film on the insulating film that is formed on the internal surface of the hole.

7. The semiconductor apparatus as set forth in claim 1, wherein:
the penetration electrode includes a hole-filling section formed in the hole.

8. The semiconductor apparatus as set forth in claim 7, wherein:
the hole-filling section is made of an insulating material.

9. The semiconductor apparatus as set forth in claim 7, wherein:
the hole-filling section is made of an electrically conductive material.

10. A method for manufacturing a semiconductor apparatus including (i) a field oxide film formed in a surface of a semiconductor substrate, (ii) an electrode formed on the field oxide film, and (iii) a penetration electrode that penetrates the field oxide film and the semiconductor substrate, respectively, and that is electrically connected to the electrode,
said method, comprising the steps of:
(a) forming an aperture section in the field oxide film so that the semiconductor substrate is exposed in the aperture section;
(b) forming a hole in an area of the semiconductor substrate, the area being exposed in the aperture section of the filed oxide film;
(c) forming an insulating film on an internal surface of the hole, and
(d) forming an electrically conductive film on the insulating film formed,
the steps (c) and (d) forming the penetration electrode.

11. The method for manufacturing a semiconductor as set forth in claim 10, wherein:
the step (c) includes the step of:
(e) printing an insulating material under a certain air pressure so that the hole is covered, and then increasing the air pressure more than the certain air pressure so that a film made of the insulating material is formed on the internal surface of the hole.

12. The method as set forth in claim 11, wherein:
the step (e) is repeated more than once.

13. The method as set forth in claim 11, wherein:
the step (d) includes the step of:
(f) printing an electrically conductive material under a certain air pressure so that the hole is covered, and then increasing the air pressure more than the certain air pressure so that a layer made of the electrically conductive layer is formed on the internal surface of the hole.

14. The production method of a semiconductor as set forth in claim 13, wherein:
the step (f) is repeated more than once.

15. The production method of a semiconductor as set forth in claim 10, further comprising the step of:
(g) forming a hole-filling section in the hole,
the step (g) including the step of:
(h) printing an insulating material or an electrically conductive material under a certain air pressure so that the hole is covered, and then increasing the air pressure more than the certain air pressure so that the hole is filled with the insulating material or the electrically conductive material.

16. The method as set forth in claim 15, wherein:
the step (h) is repeated more than once so as to fill the hole with the insulating material or the electrically conductive material.
